(19) United States
(12) Patent Application Publication
(10) Pub. No.: US 2016/0043257 A1
(43) Pub. Date: Feb. 11, 2016

(54) Hermetic Module

(71) Applicant: Solatics Ltd., Beit Elazari (IL)

(72) Inventors: Sharone Zehavi, Cupertino, CA (US); Neta Reef, Beit Elazari (IL)

(21) Appl. No.: 14/453,568

(22) Filed: Aug. 6, 2014

(51) Int. Cl. H01L 31/048; H01L 31/0203; H01L 31/18

(52) U.S. Cl. CPC H01L 31/0481; H01L 31/18; H01L 31/0203

(57) ABSTRACT

A frameless, hermetic module comprising two or more active regions for converting radiation to electrical energy comprising at least two polymeric layers encasing the active regions such that the active regions are hermetically sealed is disclosed.

### CROSS-REFERENCE TO RELATED APPLICATIONS

This application is related in part to U.S. applications Ser. Nos. 12/789,357, 13/010,700, 13/019,965, 13/077,870, 13/104,881, 13/272,073, 13/273,175, 13/300,046, 13/708,454 U.S.2010/0304035, U.S.2011/0045630, U.S.2011/0192461, U.S.2012/0247543, US 2012/0273792, U.S. Pat. No. 7,789,331, U.S. Pat. No. 8,110,419, U.S. Pat. No. 8,153,528, U.S. Pat. No. 8,253,528, and U.S. Pat. No. 8,476,660 all incorporated by reference in their entirety herein.

### BACKGROUND OF THE INVENTION

1. Field of the Invention

The invention discloses a frameless, hermetic module comprising one or more active regions for converting radiation to electrical energy comprising at least two polymeric layers encasing the one or more active regions such that the active regions are hermetically sealed.

2. Description of Related Art

Background material is found in the following references; all references are incorporated by reference herein in their entirety. References: U.S. Pat. No. 5,290,366; U.S. Pat. No. 6,034,322; U.S. Pat. No. 6,268,062; U.S. Pat. No. 6,274,804; U.S. Pat. No. 6,664,597; U.S. Pat. No. 7,691,731; U.S. Pat. No. 8,097,117; U.S. Pat. No. 8,381,466; U.S. Pat. No. 8,522,490; U.S. Pat. No. 8,525,191; U.S. Pat. No. 8,695,289; U.S. Pat. No. 8,697,981; U.S.2008/0298969; U.S.2008/0118749; U.S.2010/0065116; U.S.2013/0298969. None of the cited background material addresses the issue of hermeticity or the need for a low cost, easily attachable solar module.

### SUMMARY OF THE INVENTION

The instant invention discloses a hermetic module comprising one or more active regions for converting radiation to electrical energy comprising; a first portion comprising a transparent top seal layer, 110, and an transparent top shock absorber layer, 120, such that the radiation is incident upon the transparent top seal layer; a second portion under the transparent top shock absorber layer of the first portion comprising an array of at least two active layers, 125, for the converting radiation to electrical energy; and a third portion comprising a bottom shock absorber layer, 130, beneath the second portion and a bottom seal layer, 140, beneath the bottom shock absorber layer wherein the top and bottom seal layers are larger in area than the top and bottom shock absorber layers and the second portion such that an overlap of at least 1 mm of the top, 110-2 and 110-3, and bottom, 140-2 and 140-3, seal layers extend beyond the top and bottom shock absorber layers and the second portion around the periphery of the hermetic module wherein the overlap of the top seal layer is bonded to the overlap of the bottom seal layer such that a moisture resistant seal is provided, enclosing the second portion, 125, and the first, 120, and second, 130, shock absorber layers; optionally, a hermetic module further comprises a pliable attachment layer, 145, under the bottom seal layer, covering at least a portion of the bottom seal layer, operable to be bonded to an external polymer material wherein the attachment layer has an overlap, 145-1 and 145-2, of at least 2 mm of the attachment layer extending beyond on at least two sides of the periphery of the bottom seal layer. In embodiments wherein there are a plurality of active regions a top seal layer may be continuous over all of the active regions; optionally, a top shock absorber layer may be continuous over all active regions; optionally, a bottom shock absorber layer may be continuous under all active regions; optionally, a bottom seal layer may be continuous under all active regions; optionally, an attachment layer may be continuous under all active regions; optionally, one or more of the top seal layer, the bottom seal layer, top shock absorber layer, bottom shock absorber layer and the attachment layer may be continuous around the active regions.

In some embodiments a hermetic module comprises an array of active regions such that the active regions are separated by channels of at least 10 mm in width and wherein at least one opening exists in one channel in the array such that the distance between the edge of one active region to the opening is greater than about 0.5 mm and the size of the opening is greater than about 2 mm by about 2 mm and wherein the moisture resistant seal is provided around the periphery of the array.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a schematic view of the optional layer structure of a hermetic module.

FIG. 2 is a schematic view of a first exemplary hermetic module.

FIG. 3 is a schematic view of a second exemplary hermetic module.

FIGS. 4A and 4B are schematic views of two different hermetic solar modules.

FIG. 5 is a schematic views of an array of hermetic solar modules forming a large bundle of panels; exemplary uses are reservoir or roof or ground covers.

FIG. 6 is a schematic view of a third exemplary hermetic module.

FIG. 7 is a schematic view of a fourth exemplary hermetic module.

FIG. 8 is a schematic view of a fifth exemplary hermetic module.

FIG. 9 is a schematic view of a sixth exemplary hermetic module.

### DETAILED DESCRIPTION OF THE PREFERRED EMBODIMENTS

### Definitions

The term polymer is used expansively, including copolymers and other organics. By example, polycarbonate is a polymer containing carbonate groups; also known as Lexan®; PVC is Poly vinyl chloride; PET is polyethylene terephthalate; polyvinyl butyral (PVB), ionomer, silicone, thermoplastic polyurethane (TPU), thermoplastic polyolefin (TPO), tetrafluoroethylene hexafluoropropylene vinylidene (THV), ethyl vinyl acetate (EVA), fluorinated ethylene-propylene (FEP), saturated rubber, butyl rubber, thermoplastic elastomer (TPE), flexibilized epoxy, epoxy, urethane acrylic, acrylic, fluoroelastomers; TPO is thermoplastic PolyOlefin; PMMA is Poly (methyl methacrylate); PMMA is a transparent thermoplastic; ETFE is ethylene tetrafluoroethylene; ETFE plus carbon, C, is referred to as ECTFE. HDPE is high-density polyethylene wherein the film is fabricated after the methods of U.S.2008/0118749. Cellulose is a polysaccharide; cellulose is an important structural component of the primary cell wall of green plants, many forms of algae and the oomycetes; as used herein the term polymer includes cellulose and its plant derivatives such as cotton, wood pulp and flax or linen. DuPont™ Elvaloy® is an ethylene/vinyl acetate/carbon monoxide (E/VA/CO) copolymer, a high molecular weight copolymer often used as a non-migrating, permanent PVC plastizer in roofing, geo-membranes, and other applications needing flexible PVC; one application is as a cover for a water reservoir.

Hermetic, as used herein, is limited to moisture vapor transmission rate, MTVR, with moisture being defined as water vapor in the immediate vicinity of the module. No application to air or oxygen transmission rate is intended. In general, the materials cited, singly or in combination, have the ability to have a MTVR of between about 1 to less than 0.1 g/m²/day.

Bonded as used herein includes the acts of thermally welding, gluing, laminating or otherwise attaching one material to another through chemical or thermal means.

In some embodiments the composition of a seal layer or shock absorber layer is modified to mitigate the thermal expansion effects between the various layers including the active layer(s). The composition of a modified seal layer or shock absorber layer is chosen from two or more of a group comprising polycarbonate, PVC, PMMA, EVA, PTFE, PET, PMMA, TPU, ETFE, ECTFE, Carbon, Silicon, Glass, SiO, SiO2, Silicon Nitride and Cordierite, such that the coefficient of thermal expansion, CTE, of the modified layer is not more than 0.000038 m/m*° C., also written as 0.000038 m/m/° C.

In some embodiments the composition of the pliable attachment layer is chosen from a group consisting of polymers, PET, PMMA, Elvaloy, PVC, TPU, TPO, Polycarbonate, multi-walled polycarbonate, ETF, ETFE, ECTFE, acrylic, fiberglass, woven metal, cloth, cotton, cellulose, flax and their blends and natural constituents. The pliable attachment layer is designed to be at least 2 mm larger on at least two sides of the periphery of the bottom seal layer and/or an array of active regions; this extra overlap or skirt that protrudes is used to bond the apparatus to another substrate or surface. In one embodiment another substrate or surface is a water reservoir cover, for example, made of DuPont™ Elvaloy®. In this way a module is bonded to a reservoir cover. In some embodiments the attachment layer is bonded to a portion of a ground cover; in some embodiments the attachment layer is bonded to a portion of a roof and/or roof cover; in some embodiments one or more hermetic modules and attachment layer overlaps are attached together and are operable as a reservoir cover or a ground cover or a roof cover.

In some embodiments the top and bottom seal layers have an overlap extending around the periphery, as shown in FIGS. 2, 120-2, 120-3 and 140-2, 140-3, such a moisture resistant seal is made; in some embodiments an additional 3 mm of the bonded top and bottom seal layers, 120-1, 120-4, 140-1 and 140-4, is operable as a means for securing the hermetic module to a surface; optionally, the overlap of at least 3 mm of the top and bottom seal layers comprises means for attachment such that the hermetic module may be secured to a surface prepared with complementary means for attachment.

In some embodiments a hermetic module comprising a first portion comprising a transparent top seal layer, 110, and a transparent top shock absorber layer, 120, is between about 0.01 to about 4 mm thick and the second portion active region is between about 0.01 to about 4 mm thick. The compositions of the transparent top seal layer and the bottom seal layer are chosen from a group comprising polymers and their blends and are of a thickness between about 0.001 to about 5 millimeters. The composition of the transparent top shock absorber layer and the bottom shock absorber layer are chosen from a group comprising polymers, polyvinyl butyral (PVB), ionomer, silicone, thermoplastic polyurethane (TPU), thermoplastic polyolefin (TPO), tetrafluoroethylene hexafluoropropylene vinylidene (THV), ethyl vinyl acetate (EVA), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, fluoroelastomers and combinations thereof. Optionally, some embodiments may have more than two shock absorber layers. The thickness of each shock absorber layer may be in the range of about 10 microns to about 1,500 microns, optionally between about 25 microns to about 100 microns, and optionally between about 10 to about 25 microns. Optionally, a module may use a layer of encapsulant that is thinner than about 10 microns.

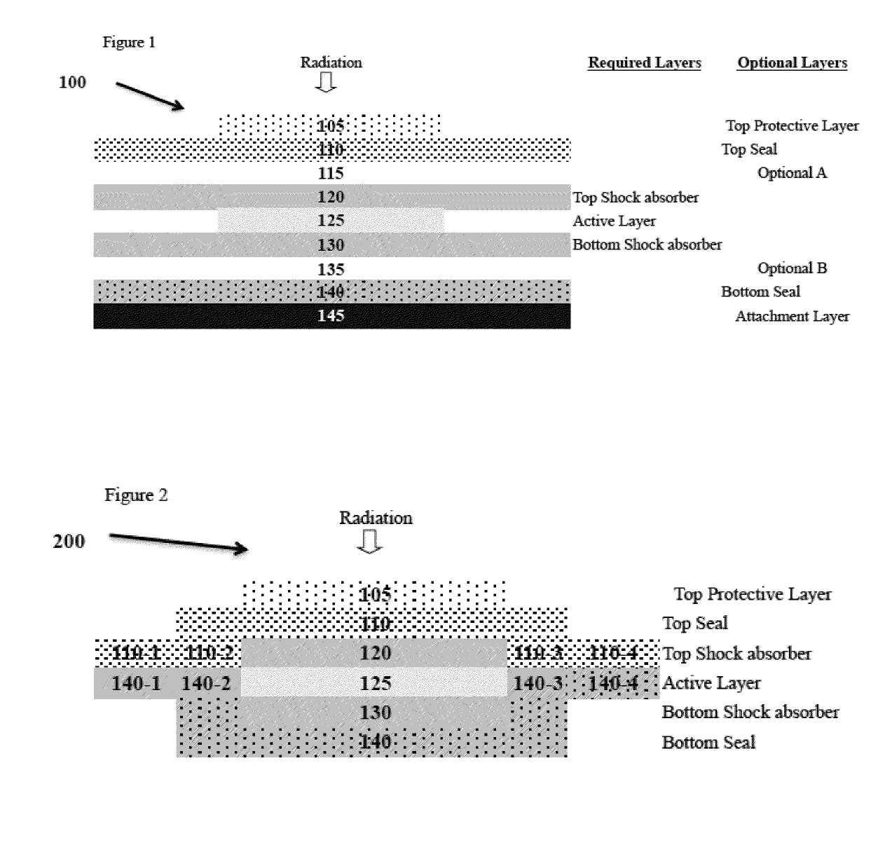

In some embodiments a hermetic module comprises a transparent, protective layer, 105, chosen from a group comprising polymers, PTFE, fluorinated polymer, ETFE, ECTFE, SiO₂, Si₃N₄, SiC, C, BN and glass, such that the transparent, protective layer thickness is between about 0.5 to about 300 micrometers, optionally between about 0.1 mm to about 4.5 mm, wherein the protective layer is placed over the top seal layer such that the incident radiation impinges upon the protective layer first. In some embodiments additional, optional, layers are added to the hermetic module structure. Optional transparent layer 115 as shown in FIG. 1 may be of a material listed for the other layers or portions; similarly for optional layer 135; layers 115 and 135 may in fact be placed anywhere in the structure; optional layers 115 and 135 may be expansion layers; optionally comprising various materials including cordierite, a magnesium iron aluminum cyclosilicate with very low thermal expansion along one axis. In some embodiments wherein only one seal layer is used, optionally a top seal layer or a bottom seal layer that seal layer may be polymeric or not; for example a seal layer may be glass.

A method of manufacturing a hermetic module 300 for converting radiation to electrical energy comprises the steps; selecting a first portion comprising an active region 125 for converting radiation to electrical energy comprising a top surface and a bottom surface and a thickness less than 350 microns; placing a top shock absorber layer 120 onto the top surface of the first portion; placing a top seal layer 110 above the top shock absorber layer with an extended portion 110-1, 110-2 and 110-3, 110-4; placing a bottom shock absorber layer 130 onto the bottom surface of the first portion; placing a bottom seal layer 140 below the bottom shock absorber layer with an extended portion 140-1, 140-2 and 140-3, 140-4; bonding the extended portion of the bottom seal layer to the extended portion of the top seal layer forming a moisture barrier 110-2/140-2 and 110-3/140-3 such that the exposed edges of the active layer and the top and bottom shock absorber layer are encased by the bonded top and bottom seal layers; optionally, attaching a flexible attachment layer 145 at least 3 mm larger than bottom seal layer along at least two sides below the bottom seal layer wherein the flexible attachment layer is operable to be bonded to another surface material or other covering materials known to one knowledgeable in the art. Optional flexible, or pliable, attachment layers 145 include those comprising cellulose, flax and/or other natural fibers such as cotton, flax, wood pulp and others known to one knowledgeable in the art.

In some embodiments a layer, optionally, transparent, of a hermetic module comprises polymers; optionally, substantially of fluorine, carbon, and hydrogen. Exemplary layer materials include fluoro-polymers, for example, ETFE, ETCFE, PFE, FEP, PVF, PCTFE or PVDF and their blends. A layer material can alternatively be, for example, a non-fluorinated polymeric material, such as polypropylene, or a polyolefin such as polypropylene, polyester such as PET.

A hermetic module for converting radiation to electrical energy a portion comprises an active region, 125, wherein the converting radiation to electrical energy occurs; in some embodiments the portion is chosen from a group consisting substantially of Group II, III, IV, V and VI elements or mixtures thereof. Additional electrical connections to the active region are required to facilitate the energy conversion and channel electrical current to a common point; these details are well known to one knowledgeable in the art. In some embodiments the active region portion comprises protection diodes, protection chips, and/or other semiconductor devices; connection cables are connected to the active region portion in the area covered by the top and bottom seal layers such that the connection cables are held in place by the top and bottom seal layers 110. 140. In these embodiments a connector may be laminated into the module between the top and bottom seal layers such that a junction box is not required, making the overall profile much thinner. In some cases an active layer comprises a support portion such as a glass layer; in these cases the combined active layer thickness may be greater than 350 microns.

In some embodiments a hermetic module comprises a plurality of active regions; optionally, the active regions are in electrical communication through wires or connectors or other means known to one knowledgeable in the art; optionally the means for electrical communication are embedded in one or more of the top seal layer, the top shock absorber layer, the bottom seal layer, the bottom shock absorber layer and the attachment layer. In some embodiments a (first) hermetic module further comprises means for electrical communication to a second hermetic module comprising top and bottom seal layers, wherein the means for electrical communication exits the (first) hermetic module between the top and bottom seal layers and is operable to enter the second hermetic module between its top and bottom seal layers wherein the means for electrical communication is chosen from a group consisting of conductive materials, electrical wires, connectors and insulation such that a junction box between the two hermetic modules is not required; optionally the second hermetic module is identical to the first hermetic module and the means for electrical communication does not include junction boxes or other electrical transformers.

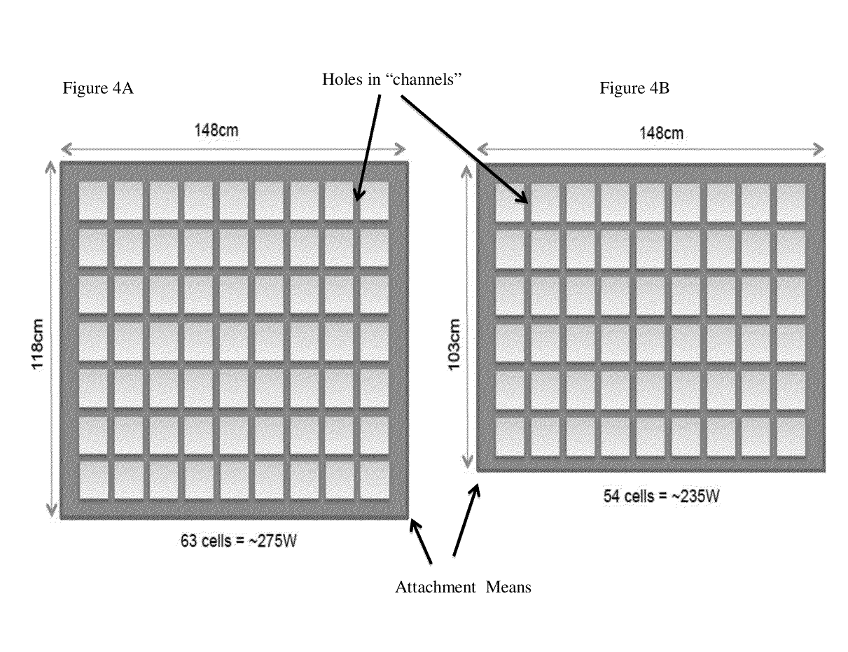

In some embodiments a hermetic module for converting radiation to electrical energy comprises an array of individual wafers, such as FIGS. 4A and 4B, wherein each wafer comprises one or more solar cells electrically connected together on the wafer; the wafers in the array are also interconnected appropriately. In this embodiment wafers may be laminated individually between sheets of various materials. Optionally, each wafer may comprise its own layers; then each wafer is attached onto a large backing sheet. In some embodiments the wafers are 5″ or more in diameter or as square tiles; in some embodiments the wafers are portions of a 6″ or larger wafers; in some embodiments the wafers are crystalline; in some embodiments the wafers are polycrystalline; in some embodiments the wafers have active regions of Group II, III, IV, V and VI elements or mixtures thereof.

In some embodiments a seal layer 110, 140, is made of “multi-wall” Polycarbonate material or material similar to it in order to reduce weight and enhance stiffness. The multi-wall Polycarbonate material layer thickness is more than about 10 micrometers and less than about 900 micrometers. Optionally, a bottom seal layer 140 is metallic, as a single layer or honeycomb or other patterns to make the structure stronger or stiffer, including “profile” or “double walls”; the thickness of a bottom metal seal layer is more than 30 microns and less then 800 microns. In some embodiments top seal and bottom seal layers are larger by at least 2 mm to allow the top and bottom seal layers to be laminated together to form a hermetic or moisture tight seal around the active portion and shock absorber layers. The lamination or thermal process step is to between about 57 and 185° C.

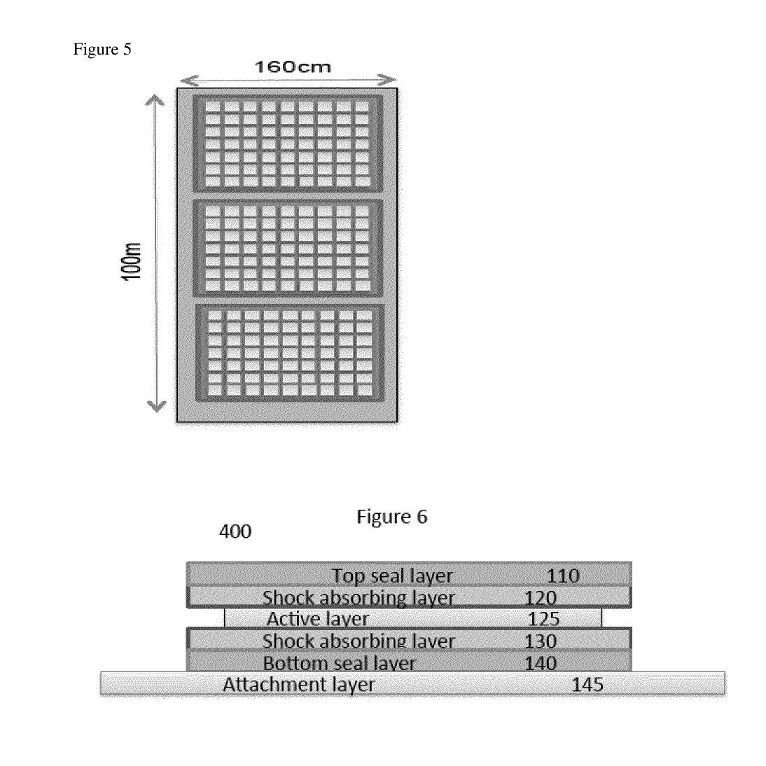

In some embodiments of a hermetic module the active regions, the PV cells, are separated by spaces or “channels” in some areas with a distance of at least 10 mm between an active region to its neighbors; in these spaces/channel areas openings are created where the minimum distance between the edge of the active region to the opening is no less the 0.5 mm and the size of the opening is no less than 2 mm. In some embodiments an array of hermetic modules is configured as cells on a large sheet, optionally polymer, as shown in FIGS. 4A and 4B. Note the placement of optional holes in the channels and the means for attachment in the periphery of the array. These arrays may be placed on an even larger sheet as shown in FIG. 5.

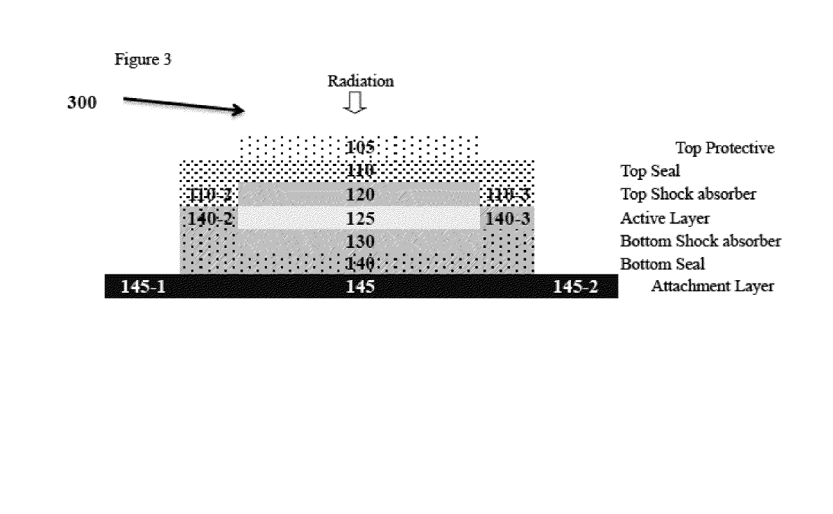

Means for attachment and complementary means for attachment as used herein are sets of devices that work together to secure one object to another; non-limiting examples include tie straps and strap holes, male/female press connectors, Velcro type connectors; Velcro straps used with slots or straps. For example, in some embodiments, bonded seal layers, 110-1/140-1 and 110-4/140-4 comprise holes along the periphery (or portion of the periphery) and the surface attachment comprises tie straps or Velcro straps or some other complementary means for attachment to the holes in the seal layer; alternatively, bonded seal layer comprises press connectors and surface comprises complementary connectors. In some embodiments, FIG. 3, portions of a pliable attachment layer, 145-1 and 145-2, extending beyond the foot print of the bottom shock absorber layer also comprise means for attachment to work in concert with complementary means for attachment on a surface of interest in a manner similar to that discussed for bonded seal layers. In some embodiments for bonded seal layer attachment or pliable attachment layer attachment bonding of the layers, including thermal welding, gluing and/or lamination, may be used.

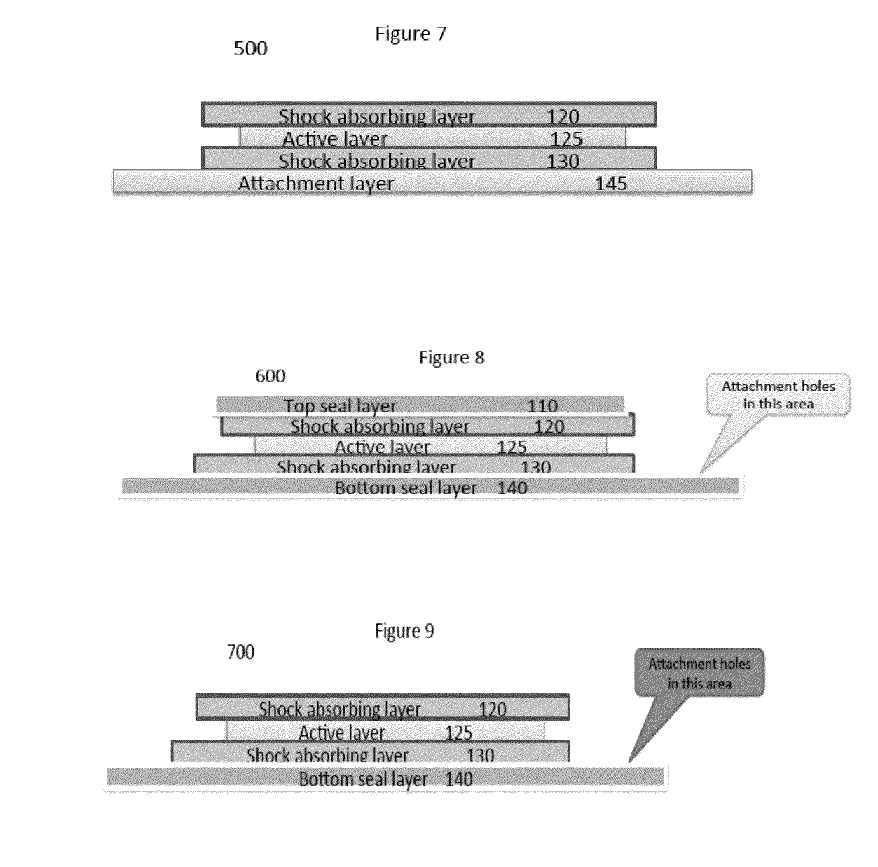

In some embodiments, not shown, only outer portions of the top seal layer 110 are used for attachment; in that instance portions 110-1 and 110-4 are present but portions 140-1 and 140-4 are not present. Alternatively, in some embodiments only outer portions of the bottom seal layer 140 are used for attachment; in that instance portions 140-1 and 140-4 are present but portions 110-1 and 110-4 are not present. Similar configurations apply when a top or bottom seal layer is not present, FIG. 7, and the attachment is done with top and bottom shock absorber layers or only the top shock absorber layer or only the bottom shock absorber layer or with an attachment layer as shown in FIG. 7. FIGS. 8 and 9 show examples of the bottom seal layer functioning as an attachment layer as well.

FIGS. 2, 3, 6,7, 8 and 9 show exemplary structures for a hermetic module. In some embodiments shock absorber layers function as a hermetic barrier around the periphery of active layers, FIGS. 7, 8 and 9. In some embodiments there may be only one seal layer, FIG. 9, optionally above or below the active layer. In some embodiments there is an attachment layer and no seal layer(s), FIG. 7. In some embodiments a top and/or bottom shock absorber layer may function as an attachment layer as noted above. A minimum configuration for a hermetic module is two shock absorbing layers hermetically protecting active layers wherein either the top and/or bottom shock absorbing layers provide means for attachment to another substrate layer such as a roof, roof cover, ground cover, or other means for covering known to one knowledgeable in the art. As environmental and operational conditions dictate additional layers including top and/or bottom seal layers, attachment layer, and layers with other functionalities, such as thermal expansion modification, may be added to a minimum configuration hermetic module to enhance its utility.

In the previous description, numerous specific details are set forth to provide a thorough understanding of the present invention. However, it will be apparent to one of ordinary skill in the art that the invention may be practiced without these particular details. In other instances, methods, procedures, and components that are well known to those of ordinary skill in the art are not described in detail to avoid obscuring aspects of the present invention.

It will be understood that when a layer is referred to as being “on top of” or “over” another layer, it can be directly on the other layer or intervening layers may also be present. In contrast, when a layer is referred to as “contacting” another layer, there are no intervening layers present. Similarly, it will be understood that when a layer is referred to as being “below” another layer, it can be directly under the other layer or intervening layers may also be present.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

I claim:

1. A hermetic module for converting radiation to electrical energy comprising;
a first portion comprising a transparent top seal layer and a transparent top shock absorber layer, such that the radiation is incident upon the transparent top seal layer;
a second portion under the transparent top shock absorber layer of the first portion comprising an array of at least two active layers for the converting radiation to electrical energy; and
a third portion comprising a bottom shock absorber layer beneath the second portion and a bottom seal layer beneath the bottom shock absorber layer wherein the top and bottom seal layers are larger in area than the top and bottom shock absorber layers such that an overlap of at least 1 mm of the top and bottom seal layers extend beyond the top and bottom shock absorber layers around the periphery of the second portion wherein the overlap of the top seal layer is bonded to the overlap of the bottom seal layer such that a moisture resistant seal is provided, enclosing the second portion and the first and second shock absorber layers.

2. The hermetic module of claim 1 wherein the array of at least two active regions are such that the active regions are separated by channels of at least 10 mm in width and wherein at least one opening exists in one channel in the array such that the distance of the edge of one active region to the opening is greater than about 0.5 mm and the size of the opening is greater than about 2 mm by about 2 mm and wherein the moisture resistant seal is provided around the periphery of the array.

3. The hermetic module of claim 1 further comprising a pliable attachment layer under the bottom seal layer, covering at least a portion of the bottom seal layer, operable to be bonded to an external surface wherein the attachment layer has an overlap of at least 2 mm of the attachment layer extending beyond on at least two sides of the periphery of the bottom seal layer.

4. The hermetic module of claim 3 wherein the composition of the pliable attachment layer is chosen from a group consisting of polymers, PET, PMMA, Elvaloy, PVC, TPU, TPO, Polycarbonate, multi-walled polycarbonate, ETF, ETFE, ECTFE, acrylic, fiberglass, woven metal, cloth, cotton, cellulose, flax and their blends and natural constituents.

5. The hermetic module of claim 3 wherein the overlap of the attachment layer is bonded to a portion of a cover for a reservoir, roof or ground cover or directly to a roof.

6. The hermetic module of claim 3 wherein one or more hermetic modules and attachment layer overlaps are attached together and operable as a reservoir cover or a ground cover or a roof cover.

7. The hermetic module of claim 1 wherein the overlap of at least one of the top and bottom seal layers around the periphery is extended such that after a moisture resistant seal is made at least an additional 3 mm of at least one of the bonded top or bottom seal layers is operable as a means for securing the hermetic module to a surface.

8. The hermetic module of claim 7 wherein the overlap of at least 3 mm of at least one of the top or bottom seal layers comprises means for attachment such that the hermetic module may be secured to a surface prepared with complementary means for attachment.

9. The hermetic module of claim 1 further comprising means for electrical communication to a second hermetic module comprising top and bottom seal layers wherein the means for electrical communication exits the hermetic module between the top and bottom seal layers and is operable to enter the second hermetic module between the top and bottom seal layers wherein the means for electrical communication is chosen from a group consisting of conductive materials, electrical wires, connectors and insulation such that a junction box between the two hermetic modules is not required.

10. The hermetic module of claim 1 further comprising a transparent, protective layer chosen from a group consisting of PTFE, fluorinated polymer, SiO₂, Si₃N₄, SiC, C, glass and BN such that the transparent, protective layer thickness is between about 0.005 mm to about 4.5 mm wherein the protective layer is placed over the top seal layer such that the incident radiation impinges upon the protective layer first.

11. The hermetic module of claim 1 wherein the compositions of the transparent top seal layer and the bottom seal layer are chosen from a group consisting of polymers, PTFE, PET, PMMA, polycarbonate, multi-wall polycarbonate, PVC, TPU, ETFE, ECTFE and their blends and are of a thickness between about 0.05 to about 4.0 millimeters.

12. The hermetic module of claim 1 wherein the compositions of the transparent top seal layer and/or the bottom seal layer are chosen from a group consisting of polymers, PTFE, PET, PMMA, polycarbonate, multi-wall polycarbonate, PVC, TPU, ETFE, ECTFE and their blends and Carbon, Silicon, Glass, SiO, SiO₂, Silicon Nitride and Cordierite such that the CTE of the top and/or bottom seal layer is not more than 0.000038 m/m*° C.

13. The hermetic module of claim 1 wherein the composition of the transparent top shock absorber layer and the bottom shock absorber layer are chosen from a group consisting of polymers, polyvinyl butyral, ionomer, silicone, thermoplastic polyurethane, thermoplastic polyolefin, tetrafluoroethylene hexafluoropropylene vinylidene, ethyl vinyl acetate, fluorinated ethylene-propylene, saturated rubber, butyl rubber, thermoplastic elastomer, flexibilized epoxy, epoxy, amorphous polyethylene terephthalate, urethane acrylic, acrylic, fluoroelastomers, Carbon, Silicon, Glass, SiO, SiO2, Silicon Nitride and Cordierite and combinations thereof.

14. The hermetic module of claim 1 wherein the composition of the active regions is chosen from a group consisting of Groups II, III, IV, V and VI elements or mixtures thereof.

15. A method of manufacturing a hermetic module for converting radiation to electrical energy comprising the steps in any order;
selecting a first portion comprising an array of at least two active regions for converting radiation to electrical energy comprising a top surface and a bottom surface ;
placing a top shock absorber layer onto the top surface of the first portion;
placing a top seal layer above the shock absorber layer with an extended portion;
placing a bottom shock absorber layer onto the bottom surface of the first portion;
placing a bottom seal layer below the bottom shock absorber layer with an extended portion;
thermally bonding the extended portion of the bottom seal layer to the extended portion of the top seal layer forming a moisture barrier such that the peripheral edges of the first portion and the top and bottom shock absorber layer are encased by the bonded top and bottom seal layers.

16. The method of claim 15 further comprising the step:
attaching a pliable attachment layer at least 3 mm larger than the bottom seal layer along at least two sides below the bottom seal layer wherein the pliable attachment layer is operable to be bonded to an external surface.

17. A hermetic module for converting radiation to electrical energy comprising;
a first portion comprising a transparent top shock absorber layer, such that the radiation is incident upon the transparent top shock absorber layer;
a second portion under the transparent top shock absorber layer of the first portion comprising an array of at least two active layers for the converting radiation to electrical energy;
a third portion comprising a bottom shock absorber layer beneath the second portion; and
a pliable attachment layer beneath the bottom shock absorber layer wherein the top and bottom shock absorber layers are larger in area than the second portion such that an overlap of at least 1 mm of the top and bottom shock absorber layers extend beyond the second portion around the periphery of the second portion wherein the overlap of the top shock absorber layer is bonded to the overlap of the bottom top shock absorber layer such that a moisture resistant seal is provided, enclosing the second portion and wherein the pliable attachment layer under the bottom shock absorber layer is operable to be bonded to an external surface wherein the attachment layer has an overlap of at least 2 mm extending beyond on at least two sides of the periphery of the bottom shock absorber layer.

18. A hermetic module for converting radiation to electrical energy comprising;
a first portion comprising a transparent top shock absorber layer, such that the radiation is incident upon the transparent top shock absorber layer;
a second portion under the transparent top shock absorber layer of the first portion comprising an array of at least two active layers for the converting radiation to electrical energy;
a third portion comprising a bottom shock absorber layer beneath the second portion; and
a seal layer placed beneath the third portion or above the first portion wherein the top and bottom shock absorber layers are larger in area than the second portion such that an overlap of at least 1 mm of the top and bottom shock absorber layers extend beyond the second portion around the periphery of the hermetic module wherein the overlap of the top shock absorber layer is bonded to the overlap of the bottom top shock absorber layer such that a moisture resistant seal is provided, enclosing the second portion and wherein the seal layer has an overlap of at least 3 mm of the seal layer extending beyond on at least two sides of the periphery of the first portion and third portion wherein the overlap of at least 3 mm of the seal layer comprises means for attachment such that the hermetic module may be secured to a surface prepared with complementary means for attachment.

19. The hermetic module of claim 18 wherein the compositions of the seal layer is chosen from a group consisting of polymers, PTFE, PET, PMMA, polycarbonate, multi-wall polycarbonate, PVC, TPU, ETFE, ECTFE and their blends and Carbon, Silicon, Glass, SiO, SiO₂, Silicon Nitride and Cordierite such that the CTE of the seal layer is not more than 0.000038 m/m*° C.
